(19) United States
(12) Patent Application Publication
(10) Pub. No.: US 2025/0275357 A1
(43) Pub. Date: Aug. 28, 2025

(54) METHOD OF MANUFACTURING LIGHT EMITTING DEVICE AND METHOD OF MANUFACTURING SEMICONDUCTOR DEVICE

(71) Applicant: CANON KABUSHIKI KAISHA, Tokyo (JP)

(72) Inventor: HIROSHI TAKAKUSAGI, Kanagawa (JP)

(21) Appl. No.: 19/046,762

(22) Filed: Feb. 6, 2025

(30) Foreign Application Priority Data
Feb. 22, 2024 (JP) 2024-025575

(51) Int. Cl. H10K 59/12; H10K 59/131; H10K 71/00

(52) U.S. Cl. CPC H10K 59/1201; H10K 59/131; H10K 71/621

(57) ABSTRACT

A method of manufacturing a light emitting device is provided. The device includes a substrate provided with an array region in which a plurality of organic light emitting elements are arranged in an array, and a peripheral region arranged adjacent to the array region. An exposure step for forming wiring patterns to be arranged in the array region and the peripheral region includes a first exposure for exposing the array region in one shot, and a second exposure for divisionally exposing the peripheral region, which is different from the first exposure. Scan exposure is used in the first exposure and the second exposure, and a scan direction in the first exposure and a scan direction in the second exposure are different.

### BACKGROUND OF THE INVENTION

### Field of the Invention

The present disclosure relates to a method of manufacturing a light emitting device and a method of manufacturing a semiconductor device.

### Description of the Related Art

In a light emitting device using an organic electroluminescence (EL) element, a light emitting device having a higher resolution and more pixels has been demanded along with the development of the virtual reality (VR) and augmented reality (AR) technologies, and as a result, a light emitting device having a larger size is demanded. However, for example, a size that an exposure apparatus used in the semiconductor fine-process technology can expose is generally about 33 mm×26 mm. When manufacturing a light emitting device having a large size, it is necessary to divide a region to expose into two or more regions and perform stitching exposure (divided exposure). International Publication No. 2013/088479 shows setting a region serving as a seam of exposure to a position where an electric wire for connecting adjacent pixel electrodes is arranged, thereby avoiding deterioration of a device characteristic.

### SUMMARY OF THE INVENTION

If a seam of stitching exposure is arranged in a region of a light emitting device where an image or the like is displayed, a pattern deviation of an electric wire at the seam or a pattern shape change for each divided and exposed region may occur. If there is a resistance variation caused by the pattern deviation at the seam or a parasitic capacitance deviation caused by the pattern shape change, unevenness derived from stitching exposure may be visually recognized in a displayed image, resulting in degradation of image quality.

Some embodiments of the present disclosure provide a technique advantageous in suppressing image quality degradation caused by stitching exposure.

According to some embodiments, a method of manufacturing a light emitting device including a substrate provided with an array region in which a plurality of organic light emitting elements are arranged in an array, and a peripheral region arranged adjacent to the array region, wherein an exposure step for forming wiring patterns to be arranged in the array region and the peripheral region comprises: a first exposure for exposing the array region in one shot; and a second exposure for divisionally exposing the peripheral region, which is different from the first exposure, scan exposure is used in the first exposure and the second exposure, and a scan direction in the first exposure and a scan direction in the second exposure are different, is provided.

According to some other embodiments, a method of manufacturing a semiconductor device including a substrate provided with an array region in which a plurality of elements are arranged in an array, and a peripheral region arranged adjacent to the array region, wherein an exposure step for forming wiring patterns to be arranged in the array region and the peripheral region comprises: a first exposure for exposing the array region in one shot; and a second exposure for divisionally exposing the peripheral region, which is different from the first exposure, scan exposure is used in the first exposure and the second exposure, and a scan direction in the first exposure and a scan direction in the second exposure are different, is provided.

Further features of the present invention will become apparent from the following description of exemplary embodiments with reference to the attached drawings.

### BRIEF DESCRIPTION OF THE DRAWINGS

FIG. 1 is a sectional view showing an example of the configuration of a light emitting device according to the embodiment.

FIG. 2 is a circuit diagram showing an example of the configuration of a pixel of the light emitting device shown in FIG. 1.

FIG. 3 is a plan view showing an example of the configuration of the light emitting device shown in FIG. 1.

FIG. 4 is a view for explaining a scan exposure method.

FIGS. 5A and 5B are views for explaining a scan direction when manufacturing the light emitting device shown in FIG. 3.

FIG. 6 is a plan view showing an example of the configuration of a boundary portion in the light emitting device shown in FIG. 3.

FIG. 7 is a plan view showing an example of the arrangement of a boundary portion in the light emitting device shown in FIG. 3.

FIG. 8 is a plan view showing a modification of the light emitting device shown in FIG. 3.

FIG. 9 is a plan view showing a modification of the light emitting device shown in FIG. 3.

FIGS. 10A and 10B are sectional views showing an example of the configuration of the pixel of the light emitting device shown in FIG. 1.

FIG. 11 is a view showing an example of a display device using the light emitting device according to the embodiment.

FIG. 12 is a view showing an example of a photoelectric conversion device using the light emitting device according to the embodiment.

FIG. 13 is a view showing an example of an electronic apparatus using the light emitting device according to the embodiment.

FIGS. 14A and 14B are views showing an example of a display device using the light emitting device according to the embodiment.

FIG. 15 is a view showing an example of an illumination device using the light emitting device according to the embodiment.

FIG. 16 is a view showing an example of a moving body using the light emitting device according to the embodiment.

FIGS. 17A and 17B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

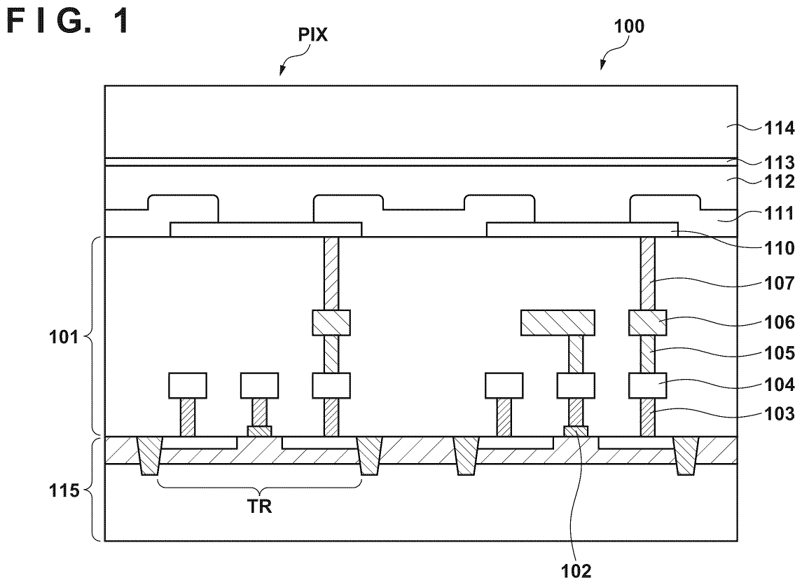

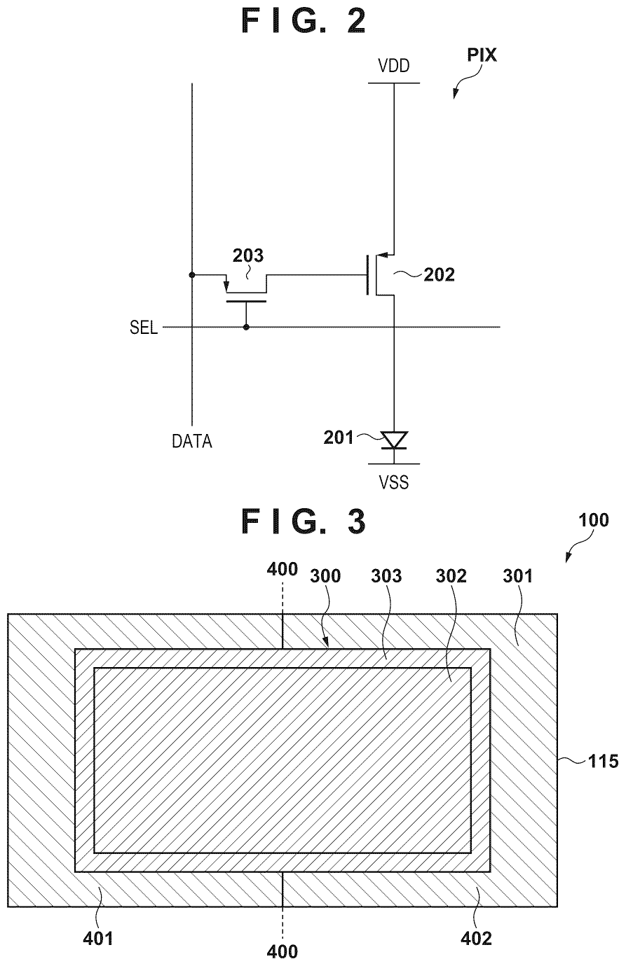

A method of manufacturing a light emitting device according to the embodiment of the present disclosure will be described with reference to FIGS. 1 to 9. FIG. 1 is a sectional view showing an example of the configuration of a light emitting device 100 manufactured using the manufacturing method according to the embodiment. FIG. 2 is a view showing an example of the configuration of a driving circuit of a pixel PIX arranged in the light emitting device 100. FIG. 3 is a plan view showing an example of the configuration of the light emitting device 100.

The light emitting device 100 includes a substrate 115 including an array region 300 in which a plurality of organic light emitting elements 201 are arranged in an array, and a peripheral region 301 arranged adjacent to the array region 300. For the substrate 115, a semiconductor substrate of single-crystal silicon, or the like can be used. However, the present invention is not limited to this, and an insulating substrate of glass or plastic provided with a semiconductor layer of polysilicon or amorphous silicon may be used as the substrate 115. A wiring structure 101 is arranged on the substrate 115 provided with a transistor TR configured to drive the organic light emitting element 201. The wiring structure 101 includes an insulator using silicon oxide or the like, wiring patterns arranged in the insulator, plugs for connecting the wiring patterns to each other, and the like. A lower electrode 110 that forms the organic light emitting element 201, an insulating layer 111, an organic layer 112 including a light emitting layer, and an upper electrode 113 are arranged on the wiring structure 101. On the organic light emitting element 201, at least one optical layer 114 can be arranged on a protection layer (not shown) configured to protect each constituent element of the pixel PIX from particles or water in the atmosphere. The optical layer 114 may include, for example, at least one of a color filter and a microlens. The optical layer 114 may have a single-layer structure or a layered structure including a plurality of layers.

The transistor TR that drives each of the plurality of organic light emitting elements 201 includes, for example, a gate electrode 102. FIG. 1 shows the wiring structure 101 having a two-layered structure including a wiring layer in which a wiring pattern 104 is arranged, and a wiring layer in which a wiring pattern 106 is arranged. Plugs 103 connected to the gate electrode 102 or the substrate 115 are arranged in the wiring structure 101. The plugs 103 connect the gate electrode 102 and the wiring pattern 104, and the substrate 115 and the wiring pattern 104. Also, a plug 105 that connects the wiring pattern 104 and the wiring pattern 106 and a plug 107 that connects the wiring pattern 106 and the lower electrode 110 are arranged in the wiring structure 101. In the configuration shown in FIG. 1, there exist two wiring layers each having a wiring pattern arranged therein. However, there may be one wiring layer or three or more wiring layers in accordance with the configuration of the light emitting device 100.

FIG. 2 shows an example of the configuration of the circuit of the pixel PIX according to this embodiment. The pixel PIX can include the organic light emitting element 201, a driving transistor 202, and a write transistor 203. The above-described transistor TR corresponds to the driving transistor 202 or the write transistor 203. In the write transistor 203, the gate electrode 102 is connected to a signal line SEL, and one main terminal (a source in the configuration shown in FIG. 2) is connected to a signal line DATA. The gate electrode 102 of the driving transistor 202 is connected to the other main terminal (a drain in the configuration shown in FIG. 2) of the write transistor 203. One main terminal (a source in the configuration shown in FIG. 2) of the driving transistor 202 is connected to a power supply line VDD, and the other main terminal (a drain in the configuration shown in FIG. 2) of the driving transistor 202 is connected to one main terminal of the organic light emitting element 201. The other main terminal of the organic light emitting element 201 is connected to a power supply line VSS. If the write transistor 203 is rendered conductive in accordance with a signal supplied to the signal line SEL, a predetermined potential is supplied as a luminance signal from the signal line DATA to the gate electrode 102 of the driving transistor 202. The driving transistor 202 supplies a current according to the potential of the luminance signal to the organic light emitting element 201. The organic light emitting element 201 thus emits light in a luminance according to the luminance signal (current driving).

Here, assume a case where when forming the wiring pattern 104 or the wiring pattern 106, the region to form the wiring pattern 104 or 106 is divided into two or more regions, and stitching exposure (divided exposure) is performed. The wiring patterns 104 and 106 are a wiring pattern arranged in the wiring layer closest to the gate electrode 102 of the transistor TR and a wiring pattern arranged in the second closest wiring layer to the gate electrode 102, respectively. Hence, these can be wiring patterns electrically connected to the transistor TR such as the driving transistor 202 or the write transistor 203. If stitching exposure is used, the line width of the wiring pattern 104 or 106 formed using stitching exposure may have a different value for each divided and exposed region. In addition, the overlay amount of the wiring pattern 104 or 106 to a pattern in another layer (for example, a layer formed using one-shot exposure), for example, the gate electrode 102, or the like may change. More specifically, the line width of the wiring pattern 104 may change for each region at a boundary of stitching exposure, and the parasitic capacitance between the signal line SEL and the gate electrode 102 of the driving transistor 202 may change for each region.

The parasitic capacitance between the signal line SEL and the gate electrode 102 of the driving transistor 202 affects a voltage applied from the signal line DATA to the gate electrode 102 of the driving transistor 202 when the write transistor 203 is rendered conductive. If the value of the parasitic capacitance is different, the voltage applied to the gate electrode 102 of the driving transistor 202 changes even in a case where the supplied luminance signal is the same, and the amount of the current flowing to the organic light emitting element 201 changes. That is, the amount of the current flowing to the organic light emitting element 201 varies for each exposure region in stitching exposure, and the light emission intensity of the organic light emitting element 201 may change at the boundary of stitching exposure.

The plan view of FIG. 3 shows a region formed using one-shot exposure and a region formed using stitching exposure (divided exposure) when manufacturing the substrate 115 included in the light emitting device 100. As described above, the substrate 115 includes the array region 300 in which the pixels PIX each including the organic light emitting element 201 are arranged in an array, and the peripheral region 301 arranged around the array region 300. The array region 300 can include an effective region 302 in which an image is actually displayed and a dummy region 303 in which dummy pixels are arranged. For example, in each pixel PIX arranged in the effective region 302, a signal is supplied from a circuit arranged in the peripheral region 301, and the organic light emitting element 201 emits light in a luminance according to the luminance signal. On the other hand, a dummy pixel arranged in the dummy region 303 has the same configuration as the pixel PIX arranged in the effective region 302 but does not emit light. For example, in the dummy pixel, the plug 107 that connects the wiring pattern 106 and the lower electrode 110 may not be arranged. A circuit configured to operate the pixel PIX, and the like can be arranged in the peripheral region 301.

An exposure step for forming wiring patterns to be arranged in the array region 300 and the peripheral region 301 in this embodiment will be described next. The exposure step of forming the wiring patterns to be arranged in the array region 300 and the peripheral region 301 includes an exposure step of exposing the array region 300 in one shot, and an exposure step of divisionally exposing the peripheral region 301, which is different from the exposure step of exposing the array region 300. That is, the array region 300 is wholly exposed in one shot, but the peripheral region 301 is divided, at a boundary 400, into an exposure region 401 and the exposure region 402, and each exposure region is exposed. Here, the wiring patterns to be formed using these exposure steps may be the wiring pattern 104 arranged in the wiring layer closest to the gate electrode 102 of the transistor TR described above and the wiring pattern 106 arranged in the second closest wiring layer to the gate electrode 102.

In this embodiment, the array region 300 is exposed in one shot. With this, when the light emitting device is manufactured using stitching exposure, it is possible to avoid a change of the light emission intensity of the organic light emitting element 201 at the boundary 400 of stitching exposure. On the other hand, the peripheral region 301 which is arranged around the array region 300 and in which the width of the region is larger than the array region 300 can be formed as a large region using stitching exposure. This can improve functionality of a circuit arranged in the peripheral region 301 or improve the degree of freedom of design. That is, it is possible to obtain the light emitting device 100 of higher performance while suppressing degradation of image quality caused by stitching exposure (divided exposure).

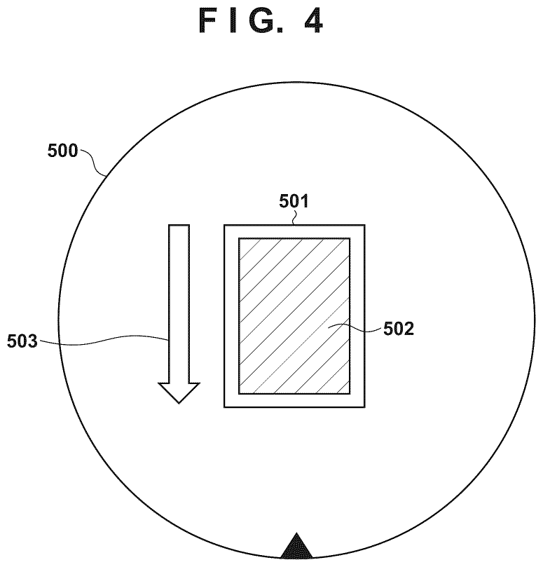

For the exposure step for forming the wiring patterns to be arranged in the array region 300 and the peripheral region 301, scan exposure may be used. Scan exposure is a method performing exposure through a slit while continuously moving a mask (reticle) and a substrate. In scan exposure, for example, as shown in FIG. 4, a pattern is formed by exposure on a substrate 500 while scanning a circuit pattern 502 drawn on a mask 501 along a scan direction 503 downward from above. The scan direction 503 is generally along the longitudinal direction of the mask 501.

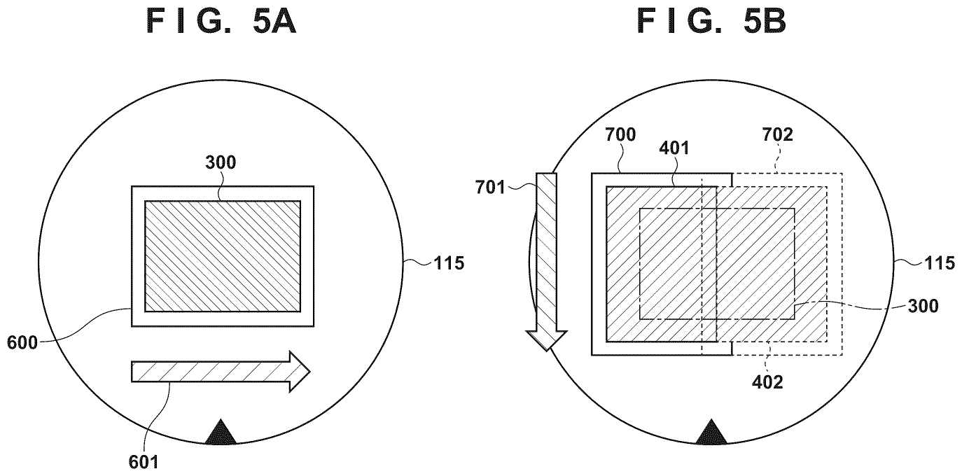

For example, as shown in FIG. 5A, the array region 300 may be exposed, using a mask 600, in one shot in a scan direction 601 along the longitudinal direction of the mask 600. Also, as shown in FIG. 5B, the exposure region 401 of the peripheral region 301 may be exposed, using a mask 700, in a scan direction 701 along the longitudinal direction of the mask 700. Similarly, the exposure region 402 of the peripheral region 301 may be exposed, using a mask 702, in the scan direction 701 along the longitudinal direction of the mask 702. In this case, considering widths necessary for the array region 300 and the exposure regions 401 and 402, as shown in FIGS. 5A and 5B, the scan direction 601 when exposing the array region 300 and the scan direction 701 when exposing the exposure regions 401 and 402 may be different. In the simplest configuration, the angle made by the scan direction 601 and the scan direction 701 is 90° or 270°, as can be understood from the notch direction of the substrate 115 shown in FIGS. 5A and 5B. However, the angle between the scan direction 601 and the scan direction 701 is not limited to 90° or 270°. If the array region 300 can be exposed in one shot and the peripheral region 301 is set at an angle that can be divisionally exposed, the angle between the scan direction 601 and the scan direction 701 can be any angle combination. Also, in FIG. 5B, at a position where the exposure regions 401 and 402 overlap the array region 300, a shutter or the like may be arranged when exposing the exposure regions 401 and 402, and the region may not be exposed. As for the exposure order of the array region 300 and the peripheral region 301, the array region 300 may be exposed first or later. Furthermore, exposure of the array region 300 may be performed between exposure of the exposure region 401 in the peripheral region 301 and exposure of the exposure region 402. However, if the scan direction of exposure is different between the array region 300 and the peripheral region 301, considering an operation such as rotation of the substrate 115, it can be more appropriate to perform exposure of the peripheral region 301 at once from the viewpoint of accuracy and efficiency.

If exposure is performed along the scan direction 601, one-shot exposure of the array region 300 is possible. However, if exposure is performed along the scan direction 701, it may be impossible to expose the array region 300 in one shot. In this case, the scan direction is changed between exposure of the array region 300 and exposure of the peripheral region 301, thereby exposing the array region 300 in one shot. Hence, the boundary of stitching exposure does not traverse the array region 300. This prevents the line widths of the patterns of the wiring patterns 104 and 106 including signal wiring patterns configured to pass signals for operating the plurality of organic light emitting elements 201 and the overlay amount with respect to the gate electrode 102 from varying at the boundary of stitching exposure. As a result, the change of the light emission intensity of the organic light emitting element 201 is avoided, and image quality degradation caused by divided exposure is suppressed.

The exposure step of exposing the array region 300 and the exposure step of exposing the peripheral region 301 (exposure regions 401 and 402) may be performed using exposure apparatuses of different specifications. For example, the resolution of the exposure apparatus used in the exposure step of exposing the array region 300 and the resolution of the exposure apparatus used in the exposure step of exposing the peripheral region 301 (exposure regions 401 and 402) may be different. For example, in the peripheral region 301, a driving circuit configured to drive the pixels PIX (organic light emitting elements 201) arranged in the array region 300 is formed. For example, in the driving circuit arranged in the peripheral region 301, elements such as transistors finer than the elements such as the driving transistor 202 and the write transistor 203 arranged in the array region 300 can be arranged. That is, of the wiring patterns 104 and 106, the wiring patterns 104 and 106 arranged in the peripheral region 301 can include wiring patterns smaller than the wiring patterns 104 and 106 arranged in the array region 300. Hence, the resolution of the exposure apparatus used in the exposure step of exposing the peripheral region 301 (exposure regions 401 and 402) may be higher than the resolution of the exposure apparatus used in the exposure step of exposing the array region 300. In this case, the wavelength of exposure light of the exposure apparatus used in the exposure step of exposing the array region 300 and the wavelength of exposure light of the exposure apparatus used in the exposure step of exposing the peripheral region 301 (exposure regions 401 and 402) may be different. For example, ArF exposure (193 nm) may be used in the exposure step of exposing the peripheral region 301 (exposure regions 401 and 402), and KrF exposure (248 nm) or i-line exposure (365 nm) may be used in the exposure step of exposing the array region 300.

The wiring patterns 104 and 106 may be patterns containing copper. Not only the wiring patterns 104 and 106 but also, among conductive patterns such as the plugs 103, 105, and 107 arranged in the wiring structure 101 (if three or more wiring layers are arranged, wiring patterns provided in these wiring layers), patterns arranged in the array region 300 are formed using one-shot exposure. On the other hand, patterns arranged in the peripheral region 301 among those conductive patterns, may be formed using stitching exposure (divided exposure). Furthermore, the same may apply to the optical layer 114 such as a color filter or a microlens arranged on the wiring structure 101. That is, the exposure step for forming the optical layer 114 may include the exposure step of exposing the array region 300 in one shot, and the exposure step of divisionally exposing the peripheral region 301, which is different from the exposure step of the array region 300.

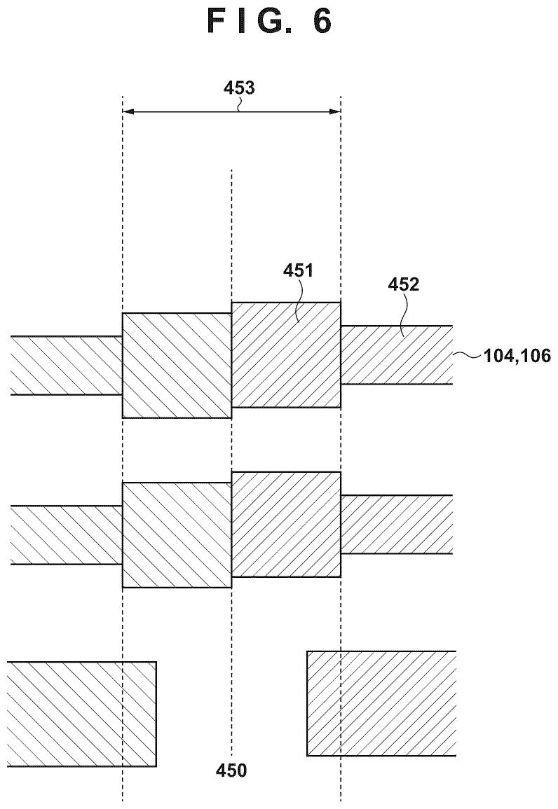

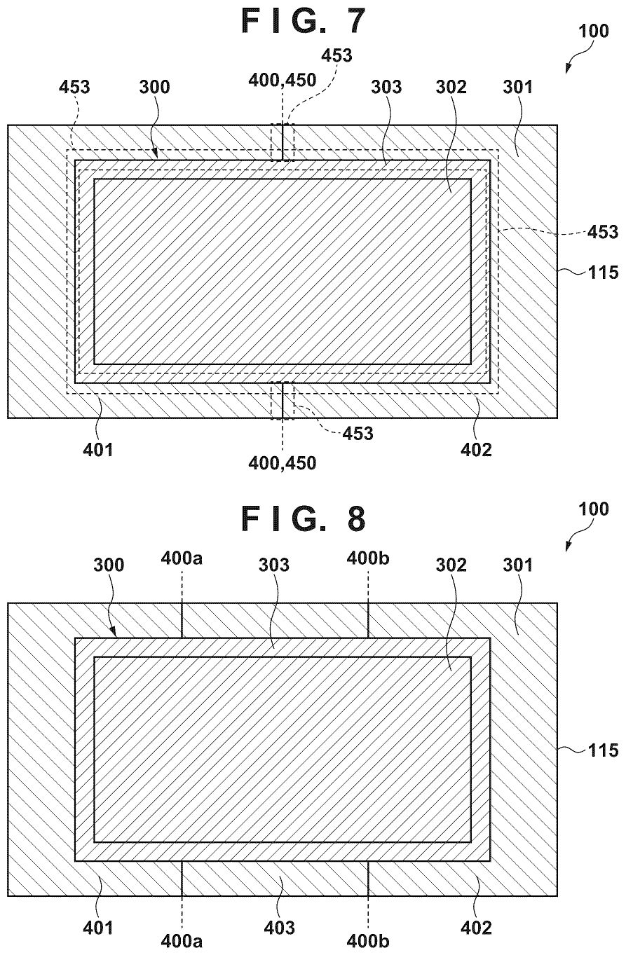

FIG. 6 is a view showing an example of the configuration of the boundary between the array region and the peripheral region and the boundary 400 between the regions that are divided and exposed in the exposure step for forming the wiring patterns in the peripheral region 301. FIG. 6 shows that the boundary between the array region and the peripheral region and the boundary 400 arranged in the peripheral region 301 are shown as a boundary 450. This is because stitching exposure (divided exposure) is performed not only between the exposure region 401 and the exposure region 402 but also between the array region 300 and the peripheral region 301 (exposure regions 401 and 402). Hence, as shown in FIG. 7, a boundary portion 453 including the boundary 450 where stitching exposure is performed is arranged.

As shown in FIG. 6, at the boundary 450, the center lines of wiring patterns adjacent to each other in the wiring patterns 104 and 106 may deviate in the same direction. The boundary 450 can thus be recognized. Also, the wiring patterns 104 and 106 include a boundary portion pattern 451 arranged in the boundary portion 453 near the boundary 450. In the boundary portion pattern 451, the width of the pattern is thicker than a wiring pattern 452 that is in contact with the boundary portion pattern 451 in the wiring patterns 104 and 106. This can suppress disconnection of the wiring pattern arranged across the boundary 450. The boundary portion 453 can be defined as a region in which the line width of the wiring pattern arranged across the boundary 450 is thicker than that before and after the boundary portion pattern 451. In addition, an alignment mark may be arranged in the boundary portion 453. This aims at increasing the connection accuracy between the wiring patterns at the boundary 450.

The optical layer 114 that can include a color filter or a microlens may have an alignment mark in the peripheral region 301. In this case, the optical layer 114 may not have any pattern other than an accessory pattern such as an alignment mark in the peripheral region 301. In other words, if a color filter is arranged as the optical layer 114, a pattern functioning as an alignment mark is formed in the peripheral region 301 using the same material as the color filter, but a pattern functioning as the color filter may not be formed. For example, in the peripheral region 301, the same layer as the color filter in the optical layer 114, except the alignment mark, may not be arranged, and a material layer (so-called solid pattern) having a predetermined film thickness may be arranged except the alignment mark. The same applies to a case where a microlens is arranged as the optical layer 114. Also, for example, the optical layer 114 may not include a pattern arranged across the array region 300 and the peripheral region 301.

In the above description, the peripheral region 301 is divided into two regions, that is, the exposure region 401 and the exposure region 402, and exposure is performed for each region. However, the number of divided regions in the exposure step when forming each component in the peripheral region 301 is not limited to two. For example, as shown in FIG. 8, the peripheral region 301 may be divided into the exposure region 401, the exposure region 402, and an exposure region 403 at boundaries 400a and 400b, and exposure may be performed for each region. Furthermore, the peripheral region 301 may be divided into four or more regions, and exposure may be performed for each region. In this case as well, the array region 300 is exposed in one shot. This can suppress image quality degradation caused by arranging the boundary of stitching exposure in the array region 300.

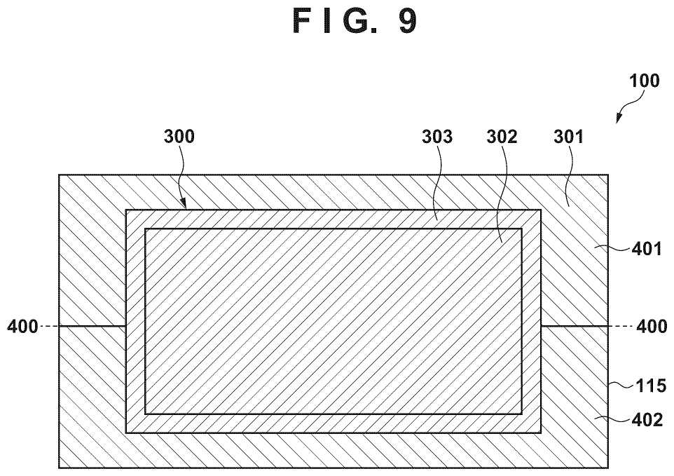

Also, in the above description, scan exposure is used to manufacture the light emitting device 100, and the scan direction when exposing the array region 300 and the scan direction when divisionally exposing the peripheral region 301 are made different. However, the present invention is not limited to this, and as shown in FIG. 9, the scan direction when divisionally exposing the peripheral region 301 may be the same as the scan direction when exposing the array region 300. The scan direction when divisionally exposing the peripheral region 301 may be appropriately determined in accordance with the sizes of the array region 300 and the peripheral region 301 and the specifications of the exposure apparatus to be used.

In the above description, when manufacturing the light emitting device 100, the array region 300 is formed using one-shot exposure, and the peripheral region 301 is formed using stitching exposure (divided exposure). However, the manufacturing method using one-shot exposure and stitching exposure in combination is not limited to use in manufacturing the light emitting device 100. For example, the above-described manufacturing method can also be used in manufacturing a semiconductor device including a substrate provided with the array region 300 in which a plurality of elements are arranged in an array. In the array region 300, a plurality of elements each having a predetermined pattern can repetitively be arranged.

For example, each of the plurality of elements arranged in the array region 300 may include a photoelectric conversion element that converts incident light into an electrical signal. A semiconductor device with a plurality of photoelectric conversion elements arranged can also be called a photoelectric conversion device or an image capturing device. In this case, if the boundary of stitching exposure is not arranged in the array region 300, an image formed using an obtained signal is prevented from including a step derived from the boundary of stitching exposure, as compared to a case where stitching exposure is performed. That is, degradation of image quality of the obtained image is suppressed.

For example, as described with reference to FIG. 5, when manufacturing a semiconductor device including the array region 300 provided with photoelectric conversion elements or the like, the scan direction when exposing the array region 300 and the scan direction when exposing the peripheral region 301 may be different. Each of the above-described embodiments can appropriately be applied to manufacturing of a semiconductor device other than the light emitting device 100.

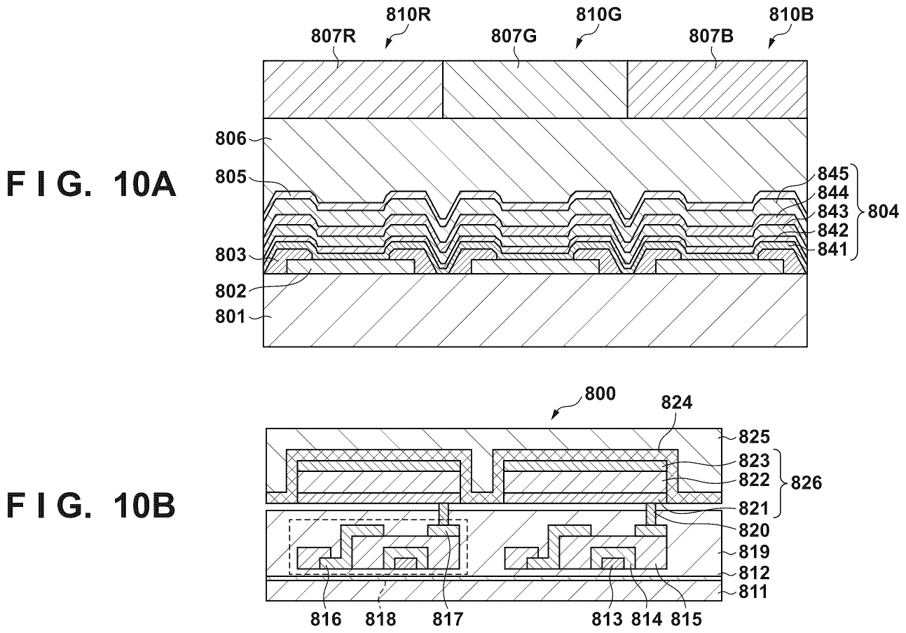

Here, application examples in which the light emitting device 100 manufactured using the manufacturing method according to this embodiment is applied to a display device, a photoelectric conversion device, an electronic apparatus, an illumination device, a moving body, and a wearable device will be described with reference to FIGS. 10A and 10B to 17A and 17B. The description will be given assuming that, for example, an organic light emitting element (OLED) such as an organic EL element using an organic light emitting material is arranged in the pixel PIX of the light emitting device 100. Details of each component arranged in the pixel PIX of the light emitting device 100 described above will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding-4.8 eV to the difference between the reduction potential of the obtained compound and that of ferrocene.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

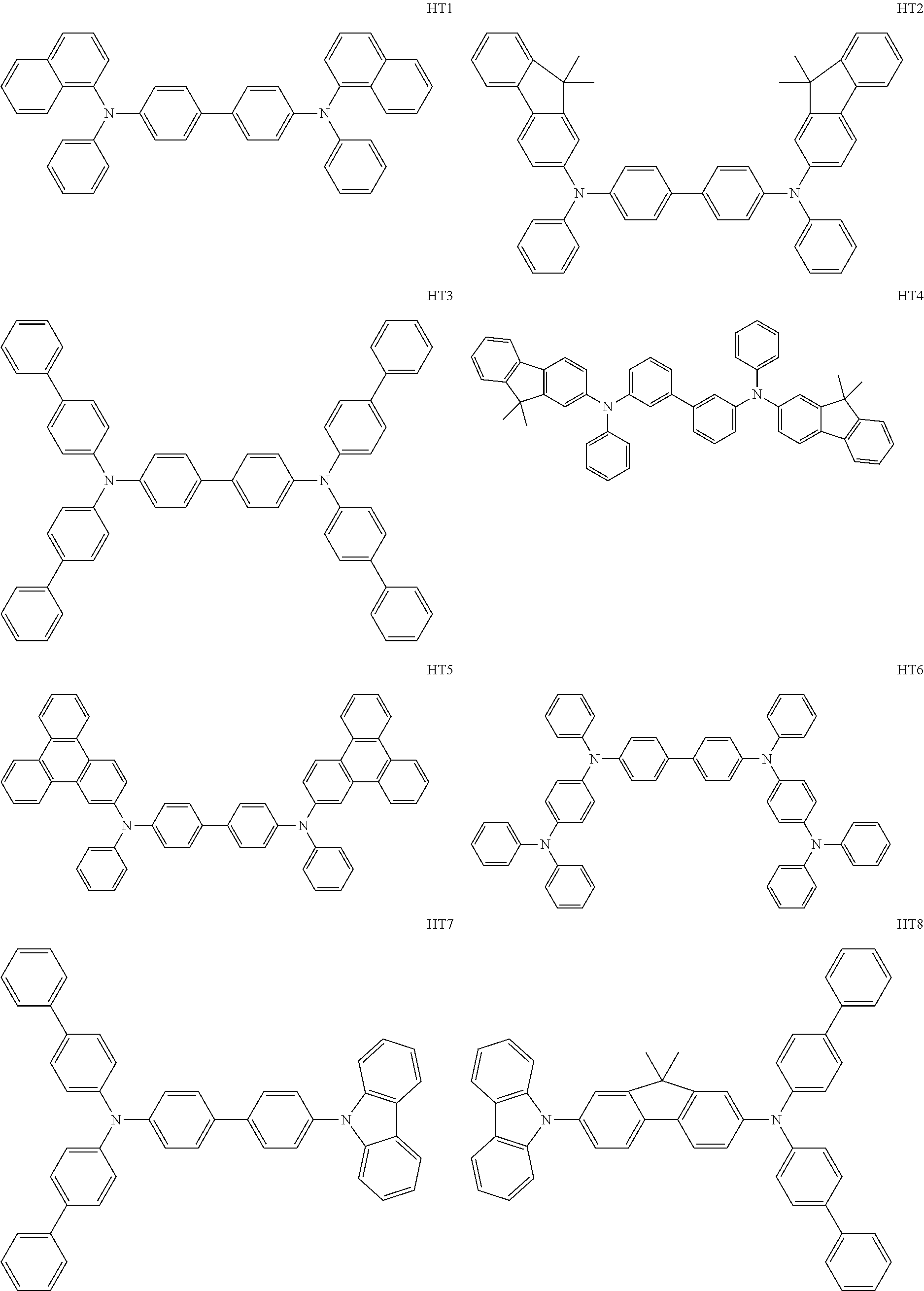

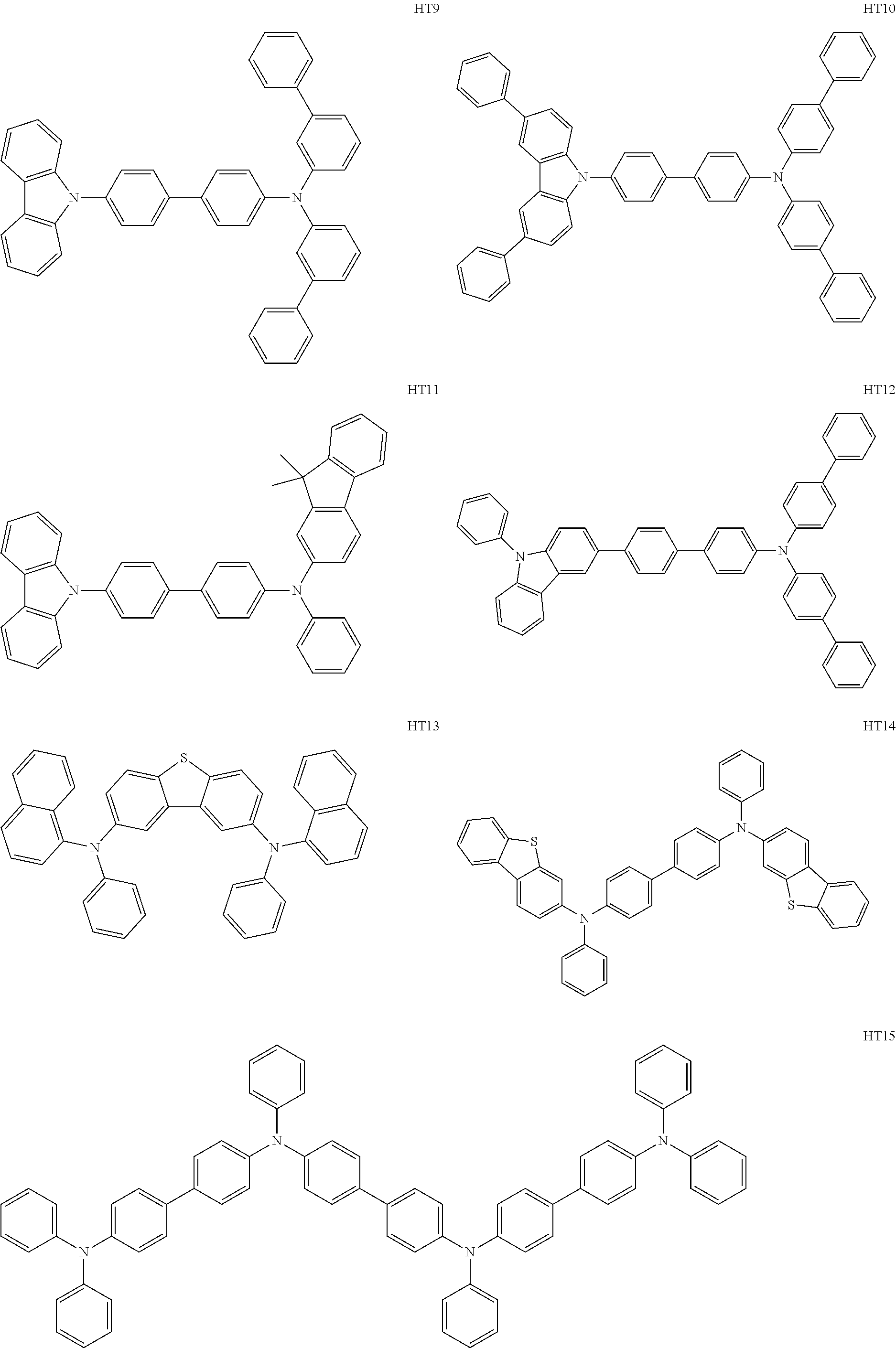

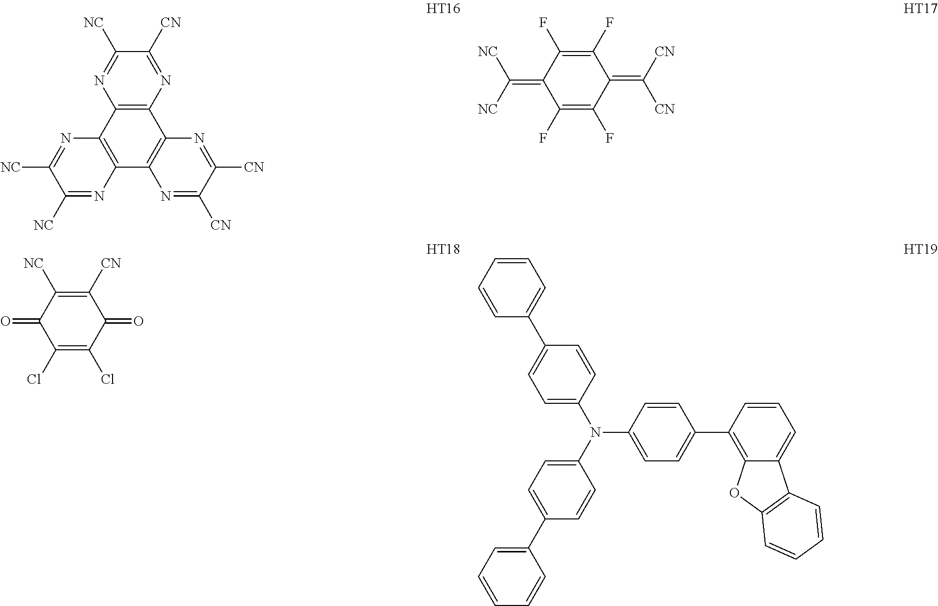

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

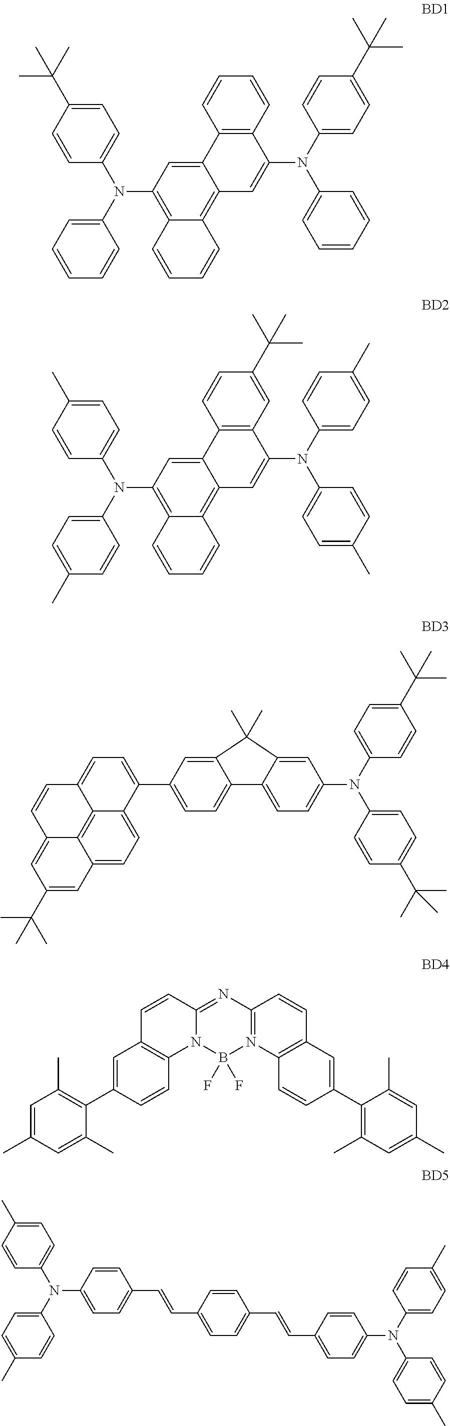

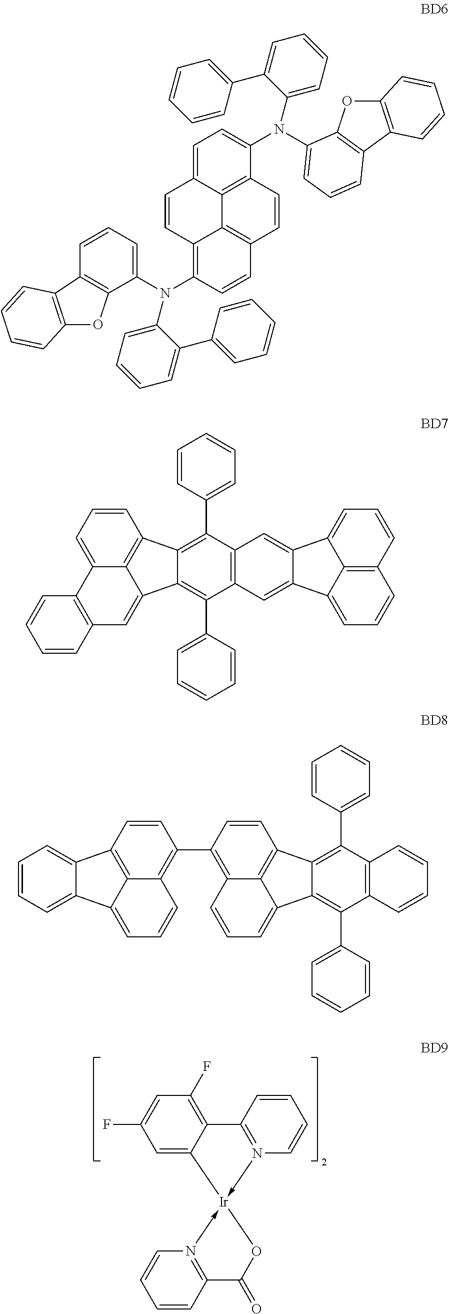

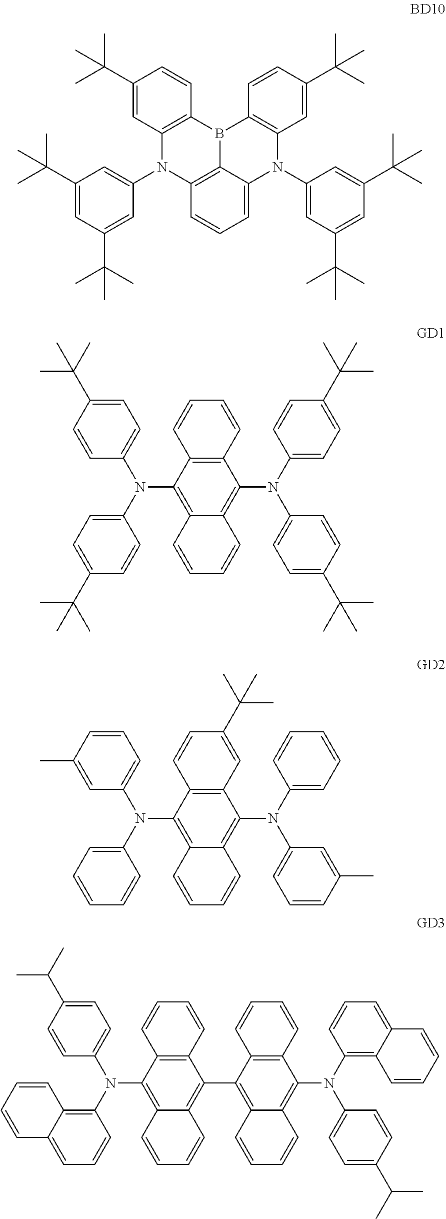

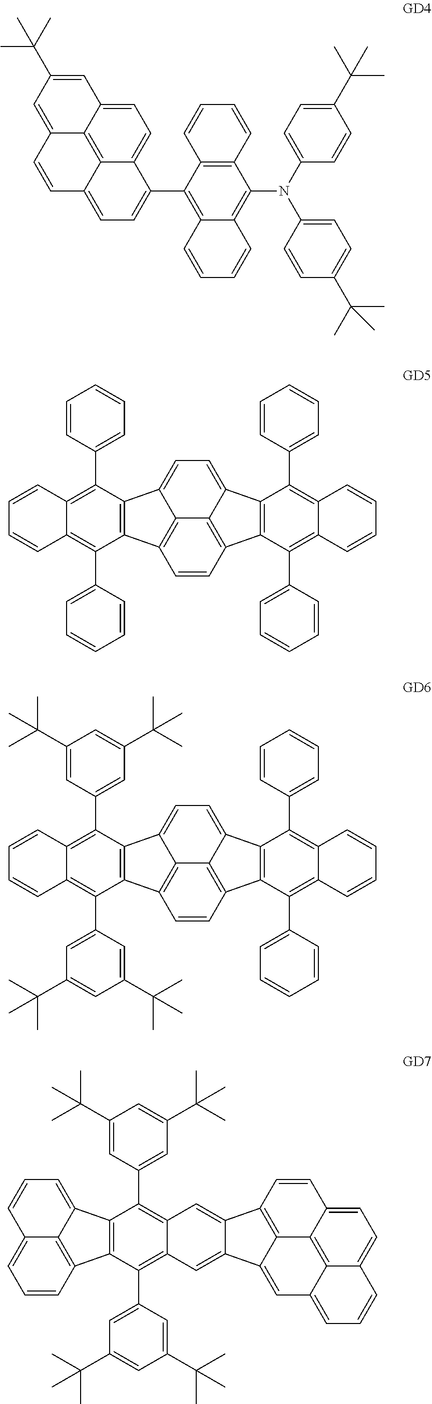

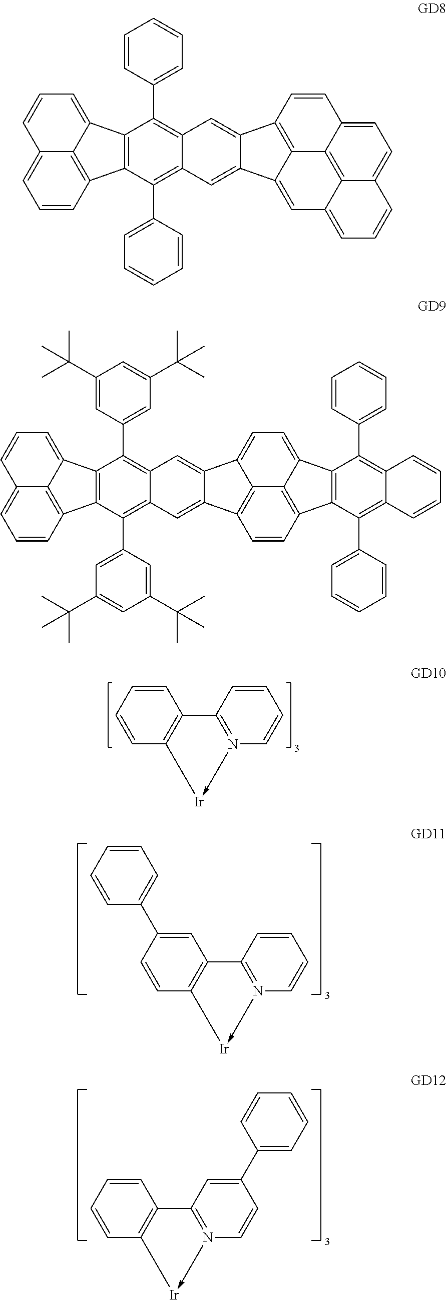

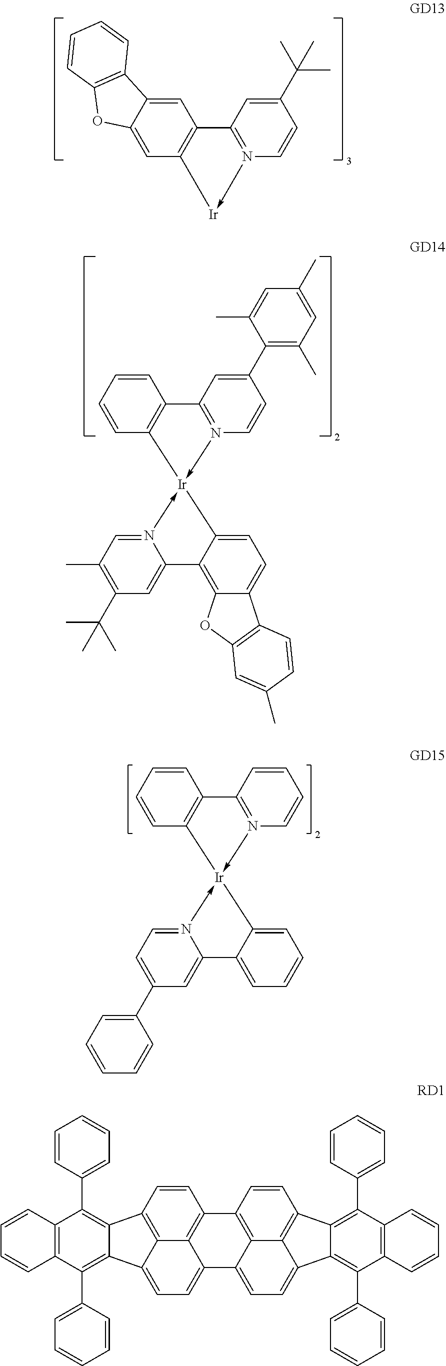

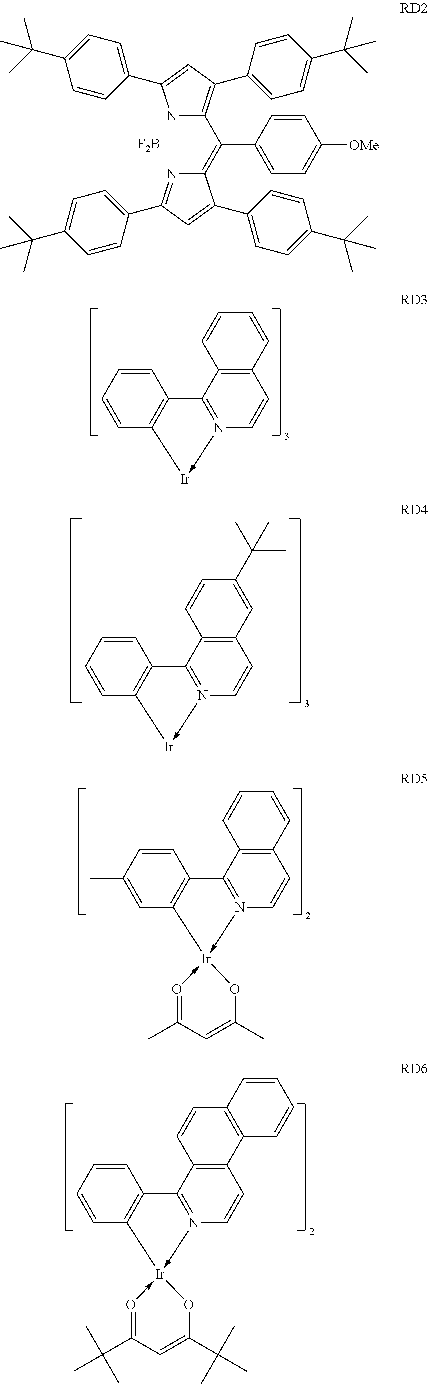

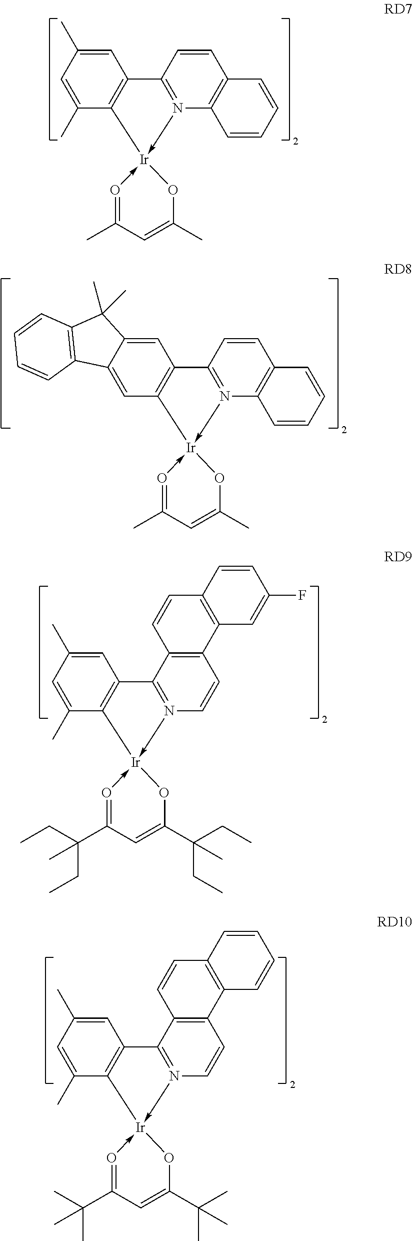

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

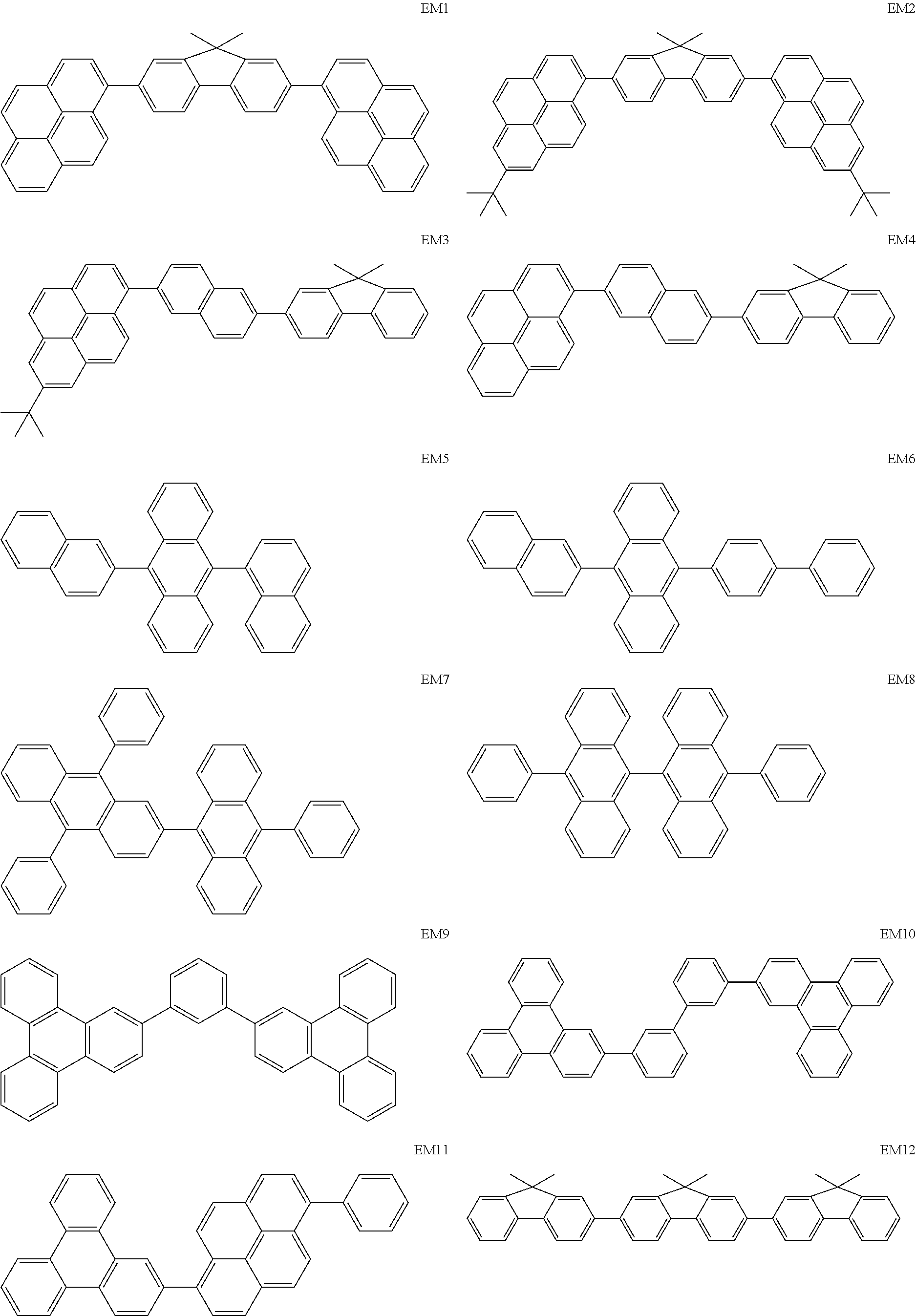

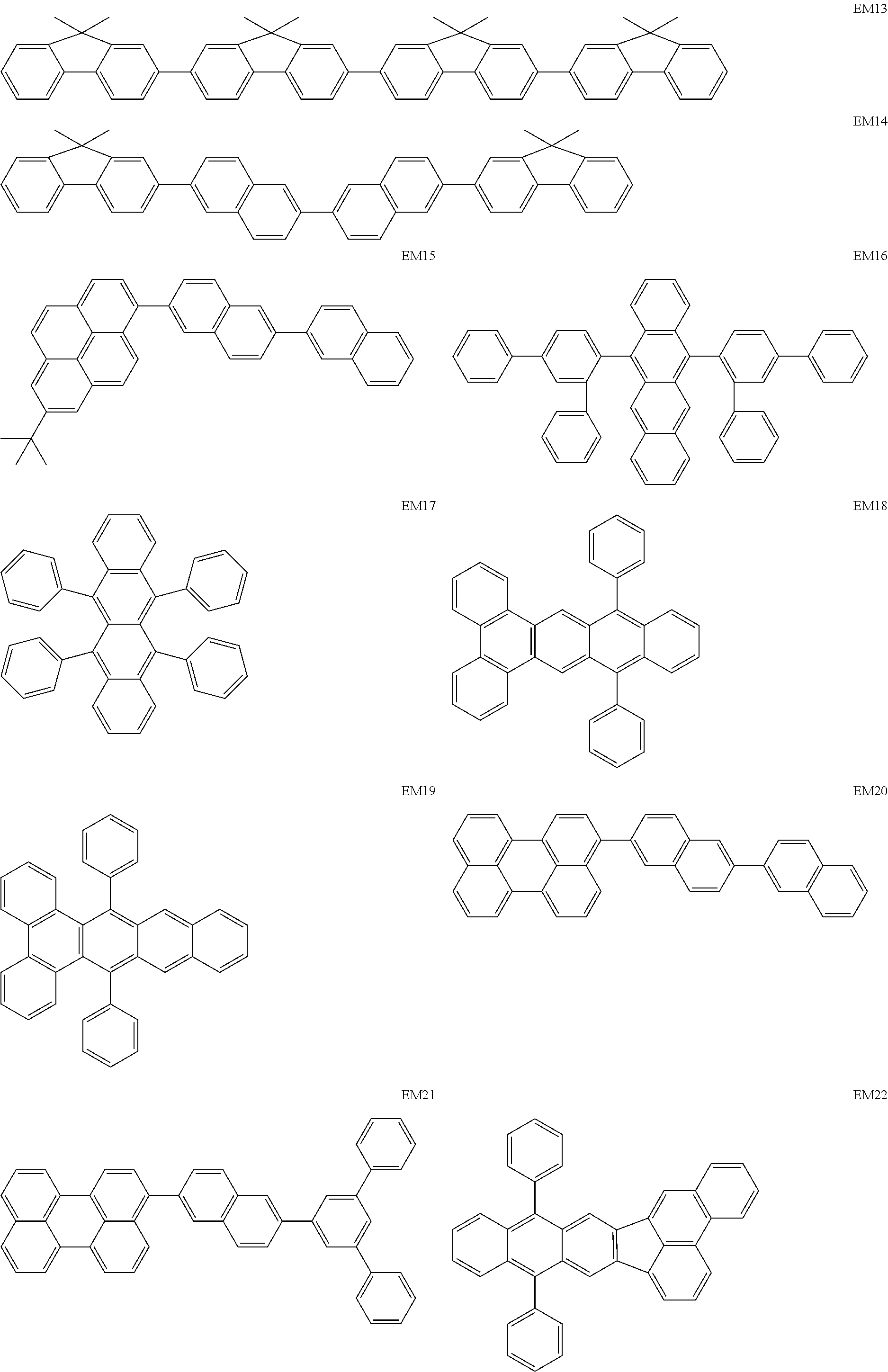

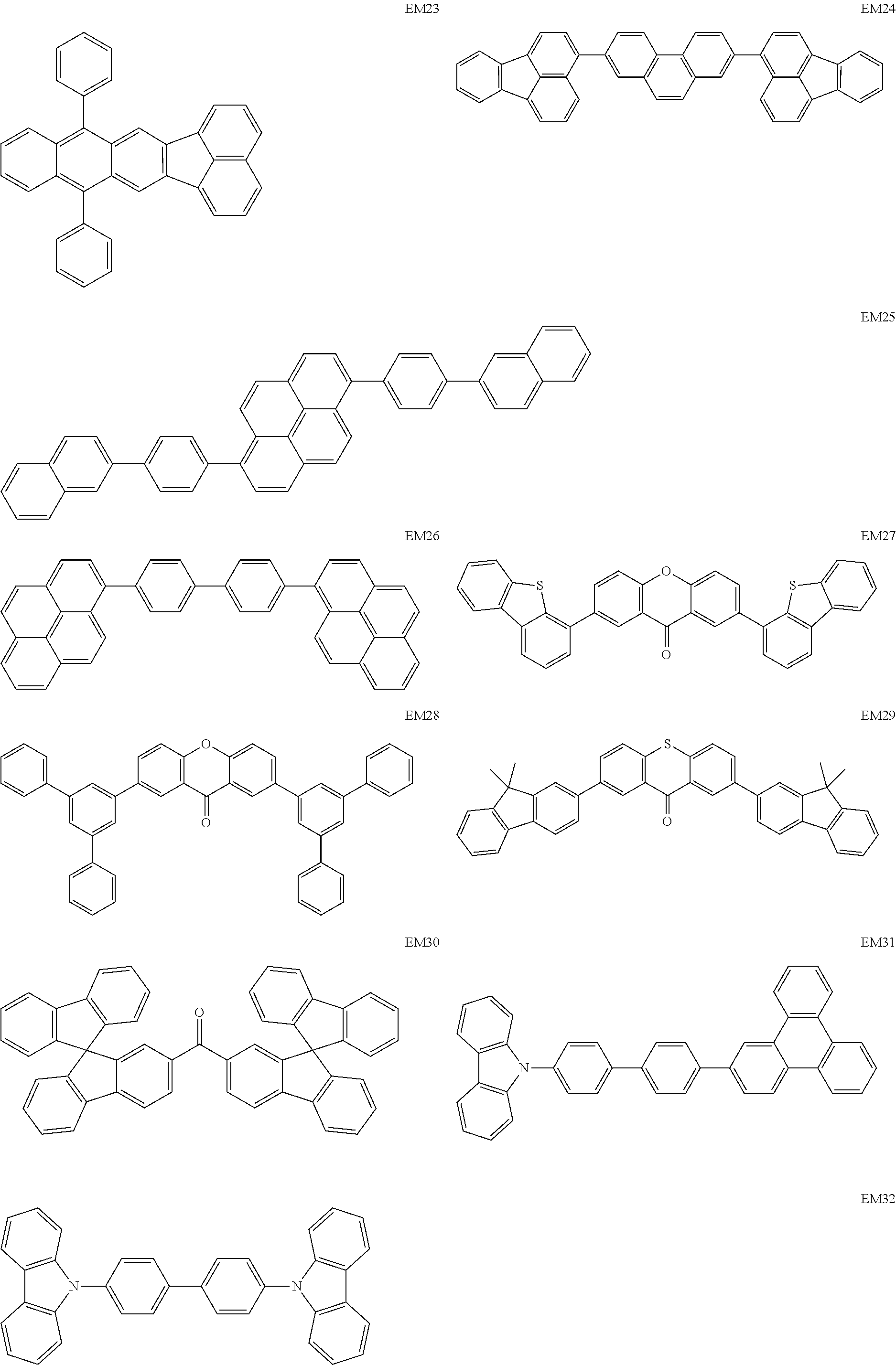

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

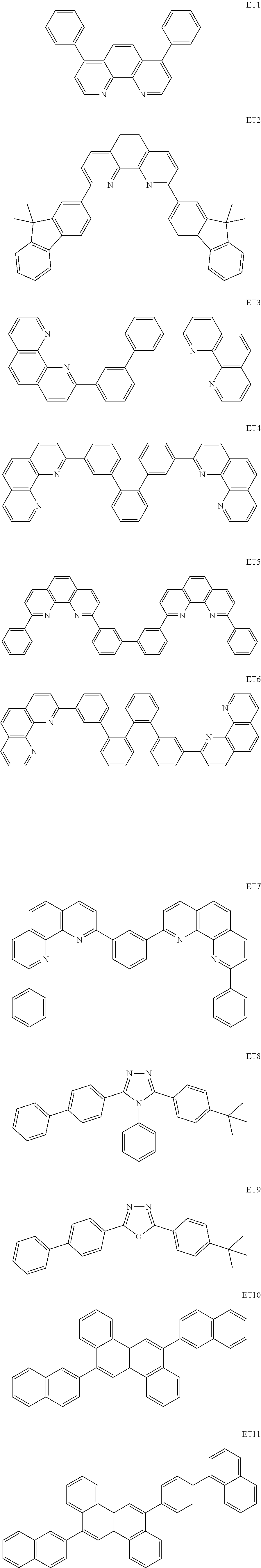

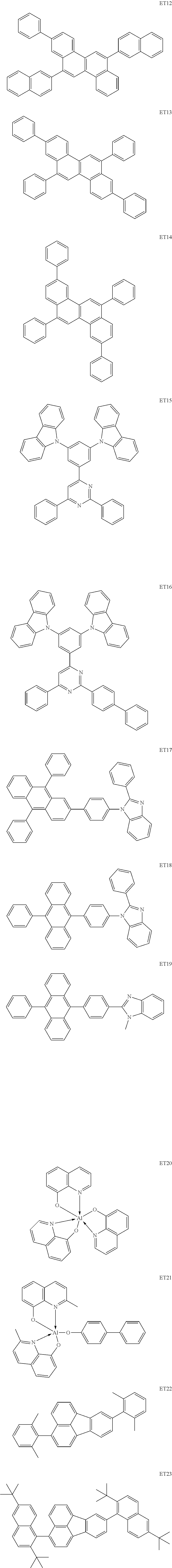

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generating portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 10A shows an example of the pixel PIX arranged in the light emitting device 100. The pixel includes sub-pixels 810 (pixels PIX). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (corresponding to the above-described light emitting device 100) shown in FIG. 10B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 10B. That is, one of the anode and cathode and one of the source electrode and drain electrode of the TFT are electrically connected. The TFT indicates a thin-film transistor.

In the display device 800 shown in FIG. 10B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 10B, but another switching element may be used instead.

The transistor used in the display device 800 shown in FIG. 10B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 10B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

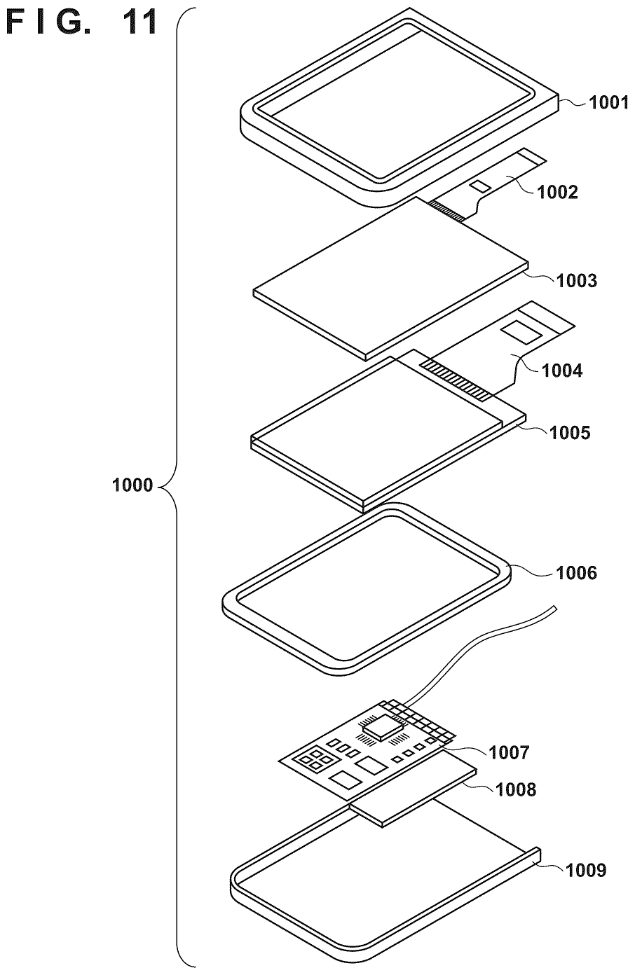

FIG. 11 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels PIX arranged in the light emitting device 100 functioning as the display panel 1005 are connected to a control circuit including the active elements such as transistors arranged on the circuit board 1007 and operate.

The display device 1000 shown in FIG. 11 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

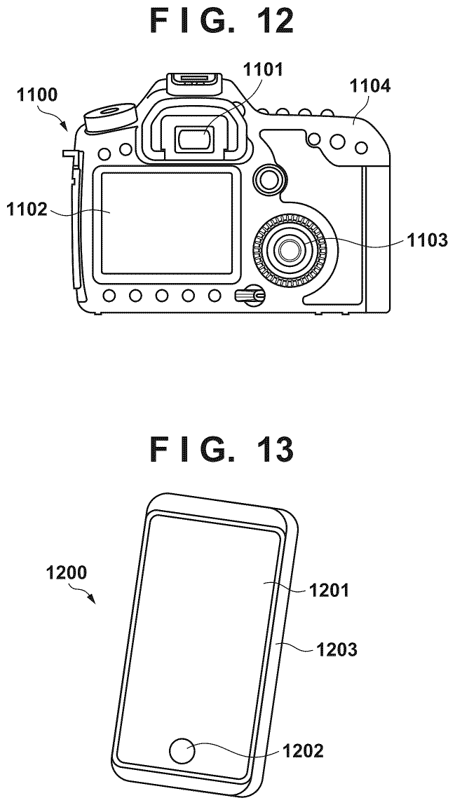

FIG. 12 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 100 in which the pixel PIX including the light emitting element using the organic light emitting material such as an organic EL element is arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 13 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

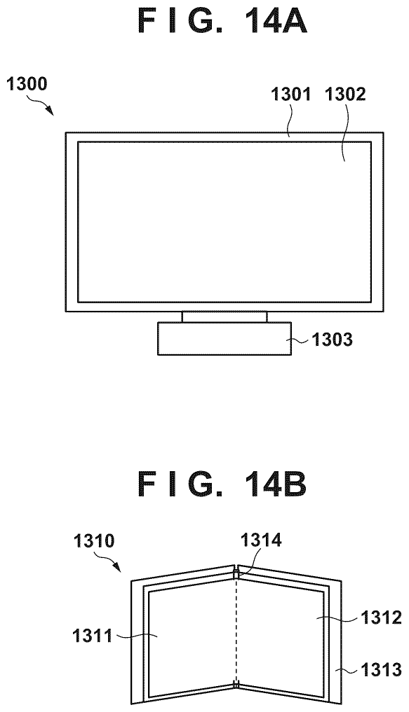

FIGS. 14A and 14B are schematic views showing examples of the display device using the light emitting device 100 according to this embodiment. FIG. 14A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 14A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 14B is a schematic view showing another example of the display device using the light emitting device 100 according to this embodiment. A display device 1310 shown in FIG. 14B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

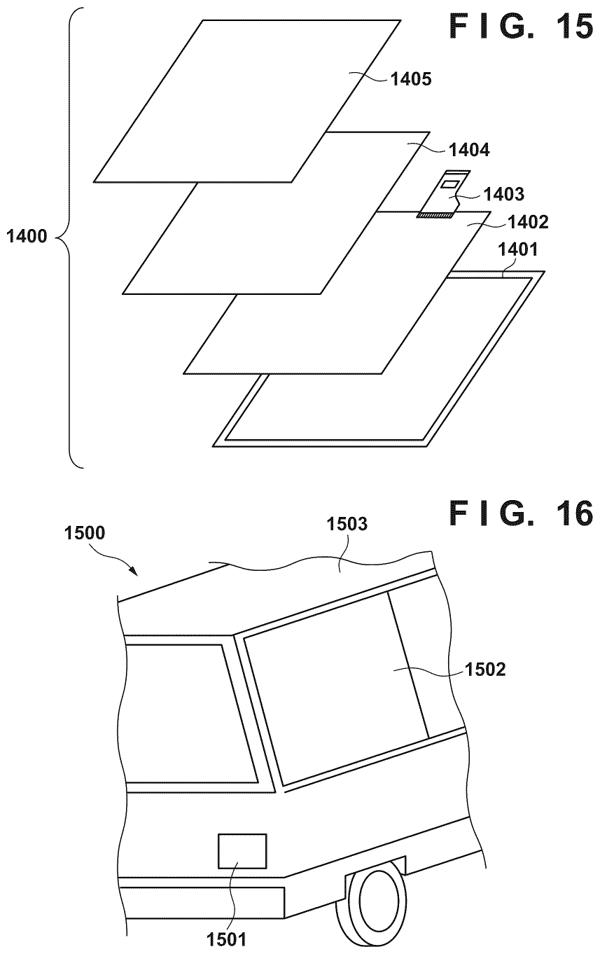

FIG. 15 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 16 is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is somewhat high, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

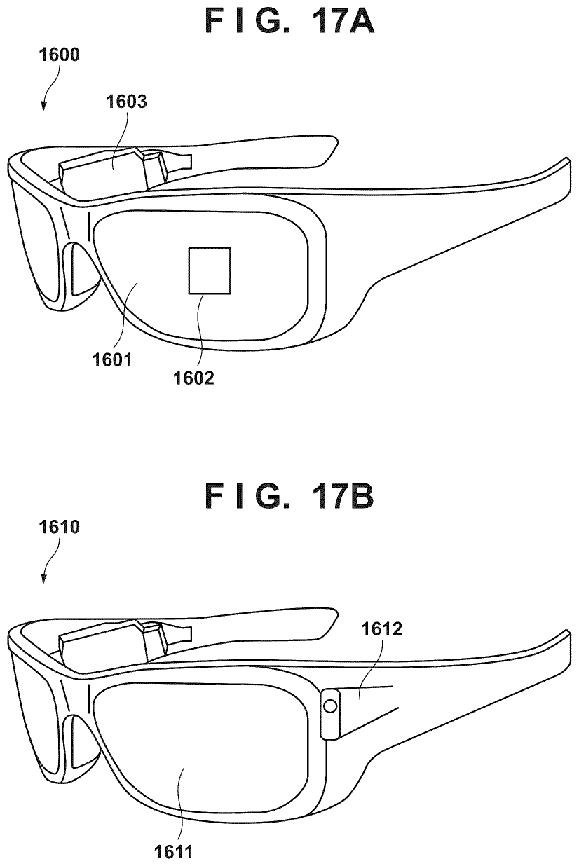

Further application examples of the light emitting device 100 according to this embodiment will be described with reference to FIGS. 17A and 17B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 17A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 17B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-025575, filed Feb. 22, 2024, which is hereby incorporated by reference herein in its entirety.

What is claimed is:

1. A method of manufacturing a light emitting device including a substrate provided with an array region in which a plurality of organic light emitting elements are arranged in an array, and a peripheral region arranged adjacent to the array region,
wherein an exposure step for forming wiring patterns to be arranged in the array region and the peripheral region comprises:
a first exposure for exposing the array region in one shot; and
a second exposure for divisionally exposing the peripheral region, which is different from the first exposure,
scan exposure is used in the first exposure and the second exposure, and
a scan direction in the first exposure and a scan direction in the second exposure are different.

2. The method according to claim 1, wherein the wiring pattern is a signal wiring pattern configured to pass a signal for operating the plurality of organic light emitting elements.

3. The method according to claim 1, wherein the first exposure and the second exposure are performed using exposure apparatuses of different specifications.

4. The method according to claim 3, wherein a resolution of the exposure apparatus used in the first exposure and a resolution of the exposure apparatus used in the second exposure are different.

5. The method according to claim 1, wherein a wiring pattern arranged in the peripheral region among the wiring patterns includes a wiring pattern smaller than a wiring pattern arranged in the array region among the wiring patterns.

6. The method according to claim 1, wherein the wiring pattern contains copper.

7. The method according to claim 1, wherein the light emitting device includes a transistor configured to drive each of the plurality of organic light emitting elements, and
the wiring pattern is at least one of a wiring pattern arranged in a wiring layer closest to a gate electrode of the transistor and a wiring pattern arranged in a second closest wiring layer to the gate electrode.

8. The method according to claim 1, wherein the substrate contains single-crystal silicon.

9. The method according to claim 1, wherein at a boundary between the array region and the peripheral region and a boundary between regions divided and exposed in the second exposure, center lines of wiring patterns adjacent to each other in the wiring patterns deviate in the same direction.

10. The method according to claim 1, wherein the wiring pattern includes a boundary portion pattern arranged at a boundary portion between the array region and the peripheral region or a boundary portion between regions divided and exposed in the second exposure, and
in the boundary portion pattern, a width of the pattern is thicker than a wiring pattern that is in contact with the boundary portion pattern in the wiring patterns.

11. The method according to claim 1, wherein an alignment mark is arranged at a boundary portion between the array region and the peripheral region or a boundary portion between regions divided and exposed in the second exposure.

12. The method according to claim 1, further comprising forming at least one optical layer including at least one of a color filter and a microlens,
wherein the forming the optical layer includes a third exposure for exposing the array region in one shot, and a fourth exposure for divisionally exposing the peripheral region, which is different from the third exposure.

13. The method according to claim 12, wherein the optical layer does not include a pattern arranged across the array region and the peripheral region.

14. The method according to claim 13, wherein the optical layer has an alignment mark in the peripheral region.

15. A method of manufacturing a semiconductor device including a substrate provided with an array region in which a plurality of elements are arranged in an array, and a peripheral region arranged adjacent to the array region,
wherein an exposure step for forming wiring patterns to be arranged in the array region and the peripheral region comprises:
a first exposure for exposing the array region in one shot; and
a second exposure for divisionally exposing the peripheral region, which is different from the first exposure,
scan exposure is used in the first exposure and the second exposure, and
a scan direction in the first exposure and a scan direction in the second exposure are different.

16. The method according to claim 15, wherein each of the plurality of elements is a photoelectric conversion element configured to convert incident light into an electrical signal.
